(19) United States
(12) Patent Application Publication
(10) Pub. No.: US 2023/0064162 A1
(43) Pub. Date: Mar. 2, 2023

(54) Semiconductor Device and Methods of Manufacture

(71) Applicant: Taiwan Semiconductor Manufacturing Co., Ltd., Hsinchu (TW)

(72) Inventors: Hsing-Chieh Lee, Hsinchu (TW); Hung-Jui Kuo, Hsinchu (TW); Ming-Tan Lee, Kaohsiung City (TW); Ting Yi Lin, Hsinchu (TW)

(21) Appl. No.: 17/461,656

(22) Filed: Aug. 30, 2021

(51) Int. Cl. G03F 7/004; H01L 23/00

(52) U.S. Cl. CPC G03F 7/0048; H01L 24/82; G03F 7/168; H01L 24/96; H01L 2224/82101

(57) ABSTRACT

A semiconductor device and method of manufacturing a semiconductor device is disclosed herein including creating a photoresist mixture that includes a surfactant, and a base solvent; one or more boiling point modifying solvents having a boiling point higher in temperature than the base solvent; and one or more hydrophilicity modifying solvents that are more hydrophilic than the base solvent; depositing the photoresist mixture onto a substrate comprising a plurality of UBMLs using a wet film process; performing a pre-bake process to cure the photoresist; and patterning the photoresist.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 2 and 5 through 7A and 8 through 13 illustrate cross-sectional views of intermediate steps during a process for forming an integrated circuit package in accordance with some embodiments.

FIGS. 3 and 4 illustrate cross-sectional views of a photoresist layer and the formation of a floating layer within the photoresist layer.

FIG. 7B illustrates a top-down view of an intermediate steps during a process for forming an integrated circuit package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, an integrated circuit package is included that uses a wet process for forming a photoresist over under-bump metallurgy layer (UBMLs) surface integrated fan-out (InFO) LSI technology. The photoresist wet film is formulated to have a higher boiling point to reduce the solvent evaporation rate, and with lower surfactant concentrations to allow air trapped during the deposition process to more easily migrate out of the photoresist prior to patterning. Because of these improvements, lower cost, higher efficiency, and increased yield of integrated circuit packages can be realized due to fewer defects resulting from surface and bulk defects of the photoresist and reduced strip time used for a wet film process over a conventional dry film lamination process.

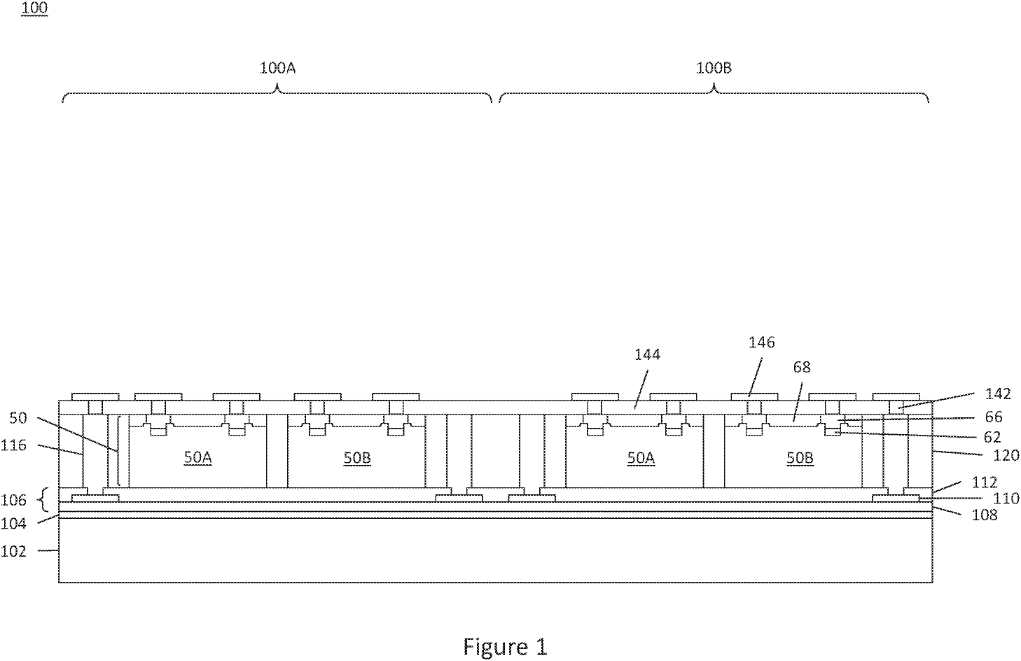

FIGS. 1, 2, and 5 through 20 illustrate cross-sectional views of intermediate steps during a process for forming an integrated circuit package 100, in accordance with some embodiments. A first package region 100A and a second package region 100B are illustrated, and one or more of the integrated circuit dies 50 are packaged to form an integrated circuit package 100 in each of the package regions 100A and 100B. The integrated circuit packages may also be referred to as integrated fan-out (InFO) packages.

In FIG. 1, a carrier substrate 102 is provided, and a release layer 104 is formed on the carrier substrate 102. The carrier substrate 102 may be a glass carrier substrate, a ceramic carrier substrate, or the like. The carrier substrate 102 may be a wafer, such that multiple packages can be formed on the carrier substrate 102 simultaneously.

The release layer 104 may be formed of a polymer-based material, which may be removed along with the carrier substrate 102 from the overlying structures that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV lights. The release layer 104 may be dispensed as a liquid and cured, may be a laminate film laminated onto the carrier substrate 102, or may be the like. The top surface of the release layer 104 may be leveled and may have a high degree of planarity.

In some embodiments, a back-side redistribution structure 106 may be formed on the release layer 104. In the embodiment shown, the back-side redistribution structure 106 includes a dielectric layer 108, a metallization pattern 110 (sometimes referred to as redistribution layers or redistribution lines), and a dielectric layer 112. The back-side redistribution structure 106 is optional. In some embodiments, a dielectric layer without metallization patterns is formed on the release layer 104 in lieu of the back-side redistribution structure 106.

The dielectric layer 108 may be formed on the release layer 104. The bottom surface of the dielectric layer 108 may be in contact with the top surface of the release layer 104. In some embodiments, the dielectric layer 108 is formed of a polymer, such as polybenzoxazole (PBO), polyimide, benzocyclobutene (BCB), or the like. In other embodiments, the dielectric layer 108 is formed of a nitride such as silicon nitride; an oxide such as silicon oxide, phosphosilicate glass (PSG), borosilicate glass (BSG), boron-doped phosphosilicate glass (BPSG), or the like; or the like. The dielectric layer 108 may be formed by any acceptable deposition process, such as spin coating, CVD, laminating, the like, or a combination thereof.

The metallization pattern 110 may be formed on the dielectric layer 108. As an example to form metallization pattern 110, a seed layer is formed over the dielectric layer 108. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist (not shown) is then formed and patterned on the seed layer. The photoresist may be formed by spin coating or the like and may be exposed to light for patterning. The pattern of the photoresist corresponds to the metallization pattern 110. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the metallization pattern 110.

The dielectric layer 112 may be formed on the metallization pattern 110 and the dielectric layer 108. In some embodiments, the dielectric layer 112 is formed of a polymer, which may be a photo-sensitive material such as PBO, polyimide, BCB, or the like, that may be patterned using a lithography mask. In other embodiments, the dielectric layer 112 is formed of a nitride such as silicon nitride; an oxide such as silicon oxide, PSG, BSG, BPSG; or the like. The dielectric layer 112 may be formed by spin coating, lamination, CVD, the like, or a combination thereof. The dielectric layer 112 is then patterned to form openings 114 exposing portions of the metallization pattern 110. The patterning may be performed by an acceptable process, such as by exposing the dielectric layer 112 to light when the dielectric layer 112 is a photo-sensitive material or by etching using, for example, an anisotropic etch. If the dielectric layer 112 is a photo-sensitive material, the dielectric layer 112 can be developed after the exposure.

The back-side redistribution structure 106 is shown in FIG. 1 as having a single metallization pattern 110 for illustrative purposes, and not intended to be limiting. In some embodiments, the back-side redistribution structure 106 may include any number of dielectric layers and metallization patterns. If more dielectric layers and metallization patterns are to be formed, steps and processes discussed above may be repeated. The metallization patterns may include one or more conductive elements. The conductive elements may be formed during the formation of the metallization pattern by forming the seed layer and conductive material of the metallization pattern over a surface of the underlying dielectric layer and in the opening of the underlying dielectric layer, thereby interconnecting and electrically coupling various conductive lines.

In some embodiments, through vias 116 are formed in the openings 114 and extend away from the topmost dielectric layer of the back-side redistribution structure 106 (e.g., the dielectric layer 112). As an example to form the through vias 116, a seed layer (not shown) is formed over the back-side redistribution structure 106, e.g., on the dielectric layer 112 and portions of the metallization pattern 110 exposed by the openings 114. In some embodiments, the seed layer is a metal layer, which may be a single layer or a composite layer comprising a plurality of sub-layers formed of different materials. In a particular embodiment, the seed layer comprises a titanium layer and a copper layer over the titanium layer. The seed layer may be formed using, for example, PVD or the like. A photoresist is formed and patterned on the seed layer. The photoresist may be formed by spin coating, or the like, and may be exposed to light for patterning. The pattern of the photoresist corresponds to conductive vias. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the through vias 116.

In some embodiments, integrated circuit dies 50 (e.g., a first integrated circuit die 50A and a second integrated circuit die 50B) are adhered to the dielectric layer 112 by an adhesive. A desired type and quantity of integrated circuit dies 50 are adhered in each of the package regions 100A and 100B. In the embodiment shown, multiple integrated circuit dies 50 are adhered adjacent to one another, including the first integrated circuit die 50A and the second integrated circuit die 50B in each of the first package region 100A and the second package region 100B. The first integrated circuit die 50A may be a logic device, such as a central processing unit (CPU), a graphics processing unit (GPU), a system-on-a-chip (SoC), a microcontroller, or the like. The second integrated circuit die 50B may be a memory device, such as a dynamic random access memory (DRAM) die, a static random access memory (SRAM) die, a hybrid memory cube (HMC) module, a high bandwidth memory (HBM) module, or the like. In some embodiments, the integrated circuit dies 50A and 50B may be the same type of dies, such as SoC dies. The first integrated circuit die 50A and second integrated circuit die 50B may be formed in processes of a same technology node, or may be formed in processes of different technology nodes. For example, the first integrated circuit die 50A may be of a more advanced process node than the second integrated circuit die 50B. The integrated circuit dies 50A and 50B may have different sizes (e.g., different heights and/or surface areas), or may have the same size (e.g., same heights and/or surface areas). The space available for the through vias 116 in the first package region 100A and the second package region 100B may be limited, particularly when the integrated circuit dies 50 include devices with a large footprint, such as SoCs. Use of the back-side redistribution structure 106 allows for an improved interconnect arrangement when the first package region 100A and the second package region 100B have limited space available for the through vias 116.

The integrated circuit dies 50 include pads 62, such as aluminum pads, to which external connections are made. The pads 62 are on the active side of the integrated circuit dies 50, such as in and/or on an interconnect structure. Die connectors 66, such as conductive pillars (for example, formed of a metal such as copper) are physically and electrically coupled to respective ones of the pads 62. The die connectors 66 may be formed by, for example, plating, or the like. The die connectors 66 electrically couple the respective integrated circuits of the integrated circuit dies 50.

Optionally, solder regions (e.g., solder balls or solder bumps) may be disposed on the pads 62. The solder balls may be used to perform chip probe (CP) testing on the integrated circuit dies 50. CP testing may be performed on the integrated circuit dies 50 to ascertain whether the integrated circuit die 50 is a known good die (KGD). Thus, only integrated circuit dies 50, which are KGDs, undergo subsequent processing and are packaged, and dies, which fail the CP testing, are not packaged. After testing, the solder regions may be removed in subsequent processing steps.

A dielectric layer 68 may (or may not) be on the active side of the integrated circuit dies 50. The dielectric layer 68 laterally encapsulates the die connectors 66. Initially, the dielectric layer 68 may bury the die connectors 66, such that the topmost surface of the dielectric layer 68 is above the topmost surfaces of the die connectors 66. In some embodiments where solder regions are disposed on the die connectors 66, the dielectric layer 68 may bury the solder regions as well. Alternatively, the solder regions may be removed prior to forming the dielectric layer 68.

The dielectric layer 68 may be a polymer such as PBO, polyimide, BCB, or the like; a nitride such as silicon nitride or the like; an oxide such as silicon oxide, PSG, BSG, BPSG, or the like; the like, or a combination thereof. The dielectric layer 68 may be formed, for example, by spin coating, lamination, chemical vapor deposition (CVD), or the like. In some embodiments, the die connectors 66 are exposed through the dielectric layer 68 during formation of the integrated circuit dies 50. In some embodiments, the die connectors 66 remain buried and are exposed during a subsequent process for packaging the integrated circuit dies 50. Exposing the die connectors 66 may remove any solder regions that may be present on the die connectors 66.

In some embodiments, the integrated circuit dies 50 are stacked devices that includes multiple semiconductor substrates. For example, the integrated circuit dies 50 may be a memory device such as a hybrid memory cube (HMC) module, a high bandwidth memory (HBM) module, or the like that includes multiple memory dies. In such embodiments, the integrated circuit dies 50 may include multiple semiconductor substrates interconnected by through-substrate vias (TSVs). Each of the semiconductor substrates may (or may not) have an interconnect structure.

In some embodiments, adhesive may be on back-sides of the integrated circuit dies 50 and adheres the integrated circuit dies 50 to the back-side redistribution structure 106, such as to the dielectric layer 112. The adhesive may be any suitable adhesive, epoxy, die attach film (DAF), or the like. The adhesive may be applied to back-sides of the integrated circuit dies 50, may be applied over the surface of the carrier substrate 102 if no back-side redistribution structure 106 is utilized, or may be applied to an upper surface of the back-side redistribution structure 106 if applicable. For example, the adhesive may be applied to the back-sides of the integrated circuit dies 50 before singulating to separate the integrated circuit dies 50.

In some embodiments, an encapsulant 120 is placed on and around the various components. After formation, the encapsulant 120 encapsulates the through vias 116 and integrated circuit dies 50. The encapsulant 120 may be a molding compound, epoxy, or the like. The encapsulant 120 may be applied by compression molding, transfer molding, or the like, and may be formed over the carrier substrate 102 such that the through vias 116 and/or the integrated circuit dies 50 are buried or covered. The encapsulant 120 is further formed in gap regions between the integrated circuit dies 50. The encapsulant 120 may be applied in liquid or semi-liquid form and then subsequently cured.

In some embodiments, a planarization process is performed on the encapsulant 120 to expose the through vias 116 and the die connectors 66. The planarization process may also remove material of the through vias 116, dielectric layer 68, and/or die connectors 66 until the die connectors 66 and through vias 116 are exposed. Top surfaces of the through vias 116, die connectors 66, dielectric layer 68, and encapsulant 120 are substantially coplanar after the planarization process within process variations. The planarization process may be, for example, a chemical-mechanical polish (CMP), a grinding process, or the like. In some embodiments, the planarization may be omitted, for example, if the through vias 116 and/or die connectors 66 are already exposed.

In some embodiments, a dielectric 144 is deposited on the integrated circuit dies 50, encapsulant 120, and through vias 116. In some embodiments the dielectric layer is formed using passivation material for LSI (PMS), or the like. In other embodiments, the dielectric 144 may be formed of a photo-sensitive material such as PBO, polyimide, BCB, other cyclic olefin copolymers, acryl-based copolymers, or the like, which may be patterned using a lithography mask. The dielectric 144 may be formed by spin coating, lamination, CVD, the like, or a combination thereof. The dielectric 144 is then patterned. The patterning forms openings exposing portions of the through vias 116 and the die connectors 66 in which conductive vias 142 are formed. The patterning may be by an acceptable process, such as by exposing and developing the dielectric 144 to light when the dielectric 144 is a photo-sensitive material, or by etching using, for example, an anisotropic etch.

In some embodiments, under-bump metallurgy layer (UBMLs) 146 are formed for connection to higher layers of the integrated circuit package 100. The UBMLs 146 have bump portions on and extending along the major surface of the dielectric 144, and have via portions extending through the dielectric 144 to physically and electrically couple the UBMLs 146 to the through vias 116 and integrated circuit dies 50. As an example to form the UBMLs 146, a seed layer is formed over the dielectric 144 and in the openings extending through the dielectric 144. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the UBMLs 146. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the UBMLs 146. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

In an embodiment the UBMLs 146 may be formed to have a thickness of between about 5 and about 10 µm. Additionally, the UBMLs 146 may also be formed to have a width of between about 5 and about 15 µm, and may be spaced apart from each other by a distance of between about 15 and about 35 µm. However, any suitable dimensions may be utilized.

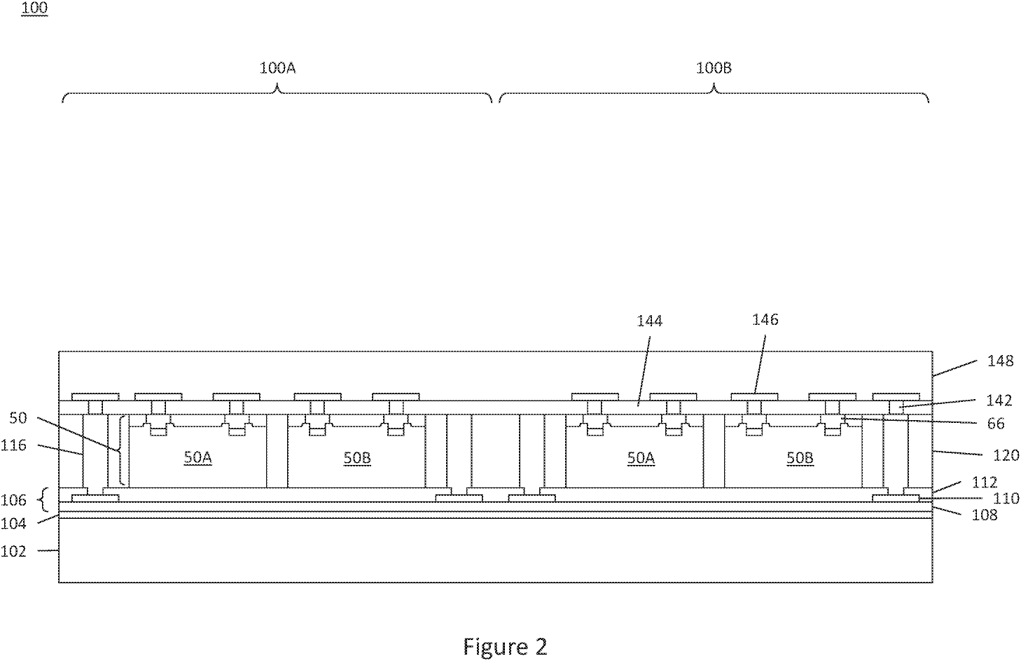

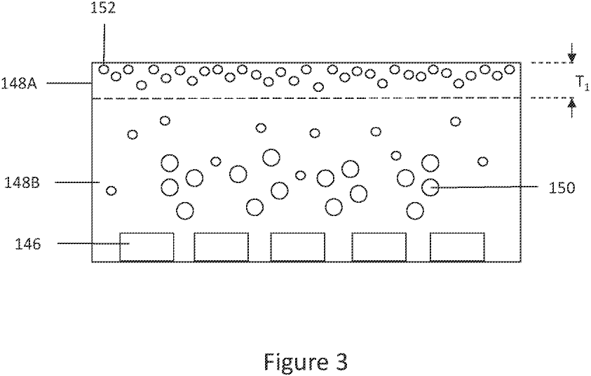

In FIG. 2, a seed layer (not shown) is first deposited over the UBMLs 146 and dielectric 144. The seed layer is a metal layer, which may be a single layer or a composite layer comprising a plurality of sub-layers formed of different materials. In a particular embodiment, the seed layer comprises a titanium layer and a copper layer over the titanium layer. The seed layer may be formed using, for example, PVD or the like. A photoresist layer 148 is then applied over the seed layer, UBMLs 146, and dielectric 144, and fills the regions between the UBMLs 146. In some embodiments the photoresist layer 148 is comprised of a polymer resin, a photoactive compound, a cross-linking monomer, and a surfactant 152 (see FIG. 3).

In an embodiment, the photoresist layer 148 includes a photoresist polymer resin along with one or more photoactive compounds (PACs) in a photoresist solvent. In an embodiment the photoresist polymer resin may comprise a hydrocarbon structure (such as an alicyclic hydrocarbon structure) that contains one or more groups that will decompose (e.g., an acid labile group) or otherwise react when mixed with acids, bases, or free radicals generated by the PACs (as further described below). In an embodiment the hydrocarbon structure comprises a repeating unit that forms a skeletal backbone of the photoresist polymer resin. This repeating unit may include acrylic esters, methacrylic esters, crotonic esters, vinyl esters, maleic diesters, fumaric diesters, itaconic diesters, (meth)acrylonitrile, (meth)acrylamides, styrenes, vinyl ethers, combinations of these, or the like.

Specific structures which may be utilized for the repeating unit of the hydrocarbon structure include methyl acrylate, ethyl acrylate, n-propyl acrylate, isopropyl acrylate, n-butyl acrylate, isobutyl acrylate, tert-butyl acrylate, n-hexyl acrylate, 2-ethylhexyl acrylate, acetoxyethyl acrylate, phenyl acrylate, 2-hydroxyethyl acrylate, 2-methoxyethyl acrylate, 2-ethoxyethyl acrylate, 2-(2-methoxyethoxy)ethyl acrylate, cyclohexyl acrylate, benzyl acrylate, 2-alkyl-2-adamantyl (meth)acrylate or dialkyl(1-adamantyl)methyl (meth)acrylate, methyl methacrylate, ethyl methacrylate, n-propyl methacrylate, isopropyl methacrylate, n-butyl methacrylate, isobutyl methacrylate, tert-butyl methacrylate, n-hexyl methacrylate, 2-ethylhexyl methacrylate, acetoxyethyl methacrylate, phenyl methacrylate, 2-hydroxyethyl methacrylate, 2-methoxyethyl methacrylate, 2-ethoxyethyl methacrylate, 2-(2-methoxyethoxy)ethyl methacrylate, cyclohexyl methacrylate, benzyl methacrylate, 3-chloro-2-hydroxypropyl methacrylate, 3-acetoxy-2-hydroxypropyl methacrylate, 3-chloroacetoxy-2-hydroxypropyl methacrylate, butyl crotonate, hexyl crotonate and the like. Examples of the vinyl esters include vinyl acetate, vinyl propionate, vinyl butylate, vinyl methoxyacetate, vinyl benzoate, dimethyl maleate, diethyl maleate, dibutyl maleate, dimethyl fumarate, diethyl fumarate, dibutyl fumarate, dimethyl itaconate, diethyl itaconate, dibutyl itaconate, acrylamide, methyl acrylamide, ethyl acrylamide, propyl acrylamide, n-butyl acrylamide, tert-butyl acrylamide, cyclohexyl acrylamide, 2-methoxyethyl acrylamide, dimethyl acrylamide, diethyl acrylamide, phenyl acrylamide, benzyl acrylamide, methacrylamide, methyl methacrylamide, ethyl methacrylamide, propyl methacrylamide, n-butyl methacrylamide, tert-butyl methacrylamide, cyclohexyl methacrylamide, 2-methoxyethyl methacrylamide, dimethyl methacrylamide, diethyl methacrylamide, phenyl methacrylamide, benzyl methacrylamide, methyl vinyl ether, butyl vinyl ether, hexyl vinyl ether, methoxyethyl vinyl ether, dimethylaminoethyl vinyl ether and the like. Examples of the styrenes include styrene, methyl styrene, dimethyl styrene, trimethyl styrene, ethyl styrene, isopropyl styrene, butyl styrene, methoxy styrene, butoxy styrene, acetoxy styrene, chloro styrene, dichloro styrene, bromo styrene, vinyl methyl benzoate, α-methyl styrene, maleimide, vinylpyridine, vinylpyrrolidone, vinylcarbazole, combinations of these, or the like.

In an embodiment, the repeating unit of the hydrocarbon structure may also have either a monocyclic or a polycyclic hydrocarbon structure substituted into it, or else the monocyclic or polycyclic hydrocarbon structure may be the repeating unit, in order to form an alicyclic hydrocarbon structure. Specific examples of monocyclic structures that may be used include bicycloalkane, tricycloalkane, tetracycloalkane, cyclopentane, cyclohexane, or the like. Specific examples of polycyclic structures that may be used include adamantine, norbornane, isobornane, tricyclodecane, tetracycododecane, or the like.

The group which will decompose, otherwise known as a leaving group or, in an embodiment in which the PAC is an photoacid generator, an acid labile group, is attached to the hydrocarbon structure so that it will react with the acids/bases/free radicals generated by the PACs during exposure. In an embodiment the group which will decompose may be a carboxylic acid group, a fluorinated alcohol group, a phenolic alcohol group, a sulfonic group, a sulfonamide group, a sulfonylimido group, an (alkylsulfonyl) (alkylcarbonyl)methylene group, an (alkylsulfonyl)(alkylcarbonyl)imido group, a bis(alkylcarbonyl)methylene group, a bis(alkylcarbonyl)imido group, a bis(alkylsylfonyl)methylene group, a bis(alkylsulfonyl)imido group, a tris(alkylcarbonyl methylene group, a tris(alkylsulfonyl)methylene group, combinations of these, or the like. Specific groups that may be utilized for the fluorinated alcohol group include fluorinated hydroxyalkyl groups, such as a hexafluoroisopropanol group. Specific groups that may be utilized for the carboxylic acid group include acrylic acid groups, methacrylic acid groups, or the like.

In an embodiment, the photoresist polymer resin may also comprise other groups attached to the hydrocarbon structure that help to improve a variety of properties of the polymerizable resin. For example, inclusion of a lactone group to the hydrocarbon structure assists to reduce the amount of line edge roughness after the photoresist layer 148 has been developed, thereby helping to reduce the number of defects that occur during development. In an embodiment the lactone groups may include rings having five to seven members, although any suitable lactone structure may alternatively be used for the lactone group.

The photoresist polymer resin may also comprise groups that can assist in increasing the adhesiveness of the photoresist layer 148 to underlying structures. In an embodiment polar groups may be used to help increase the adhesiveness, and polar groups that may be used in this embodiment include hydroxyl groups, cyano groups, or the like, although any suitable polar group may alternatively be utilized.

In some embodiments, the photoresist polymer resin may further comprise one or more alicyclic hydrocarbon structures that do not also contain a group which will decompose. In an embodiment the hydrocarbon structure that does not contain a group which will decompose may include structures such as 1-adamantyl(meth)acrylate, tricyclodecanyl (meth)acrylate, cyclohexayl (meth)acrylate, combinations of these, or the like.

Additionally, the photoresist layer 148 also comprises one or more PACs. The PACs may be photoactive components such as photoacid generators, photobase generators, free-radical generators, or the like, and the PACs may be positive-acting or negative-acting. In an embodiment in which the PACs are a photoacid generator, the PACs may comprise halogenated triazines, onium salts, diazonium salts, aromatic diazonium salts, phosphonium salts, sulfonium salts, iodonium salts, imide sulfonate, oxime sulfonate, diazodisulfone, disulfone, o-nitrobenzylsulfonate, sulfonated esters, halogenerated sulfonyloxy dicarboximides, diazodisulfones, α-cyanooxyamine-sulfonates, imidesulfonates, ketodiazosulfones, sulfonyldiazoesters, 1,2-di(arylsulfonyl)hydrazines, nitrobenzyl esters, and the s-triazine derivatives, suitable combinations of these, and the like.

Specific examples of photoacid generators that may be used include α.-(trifluoromethylsulfonyloxy)-bicyclo[2.2.1]hept-5-ene-2,3-dicarbo- ximide (MDT), N-hydroxy-naphthalimide (DDSN), benzoin tosylate, t-butylphenyl-α-(p-toluenesulfonyloxy)-acetate and t-butyl-α-(p-toluenesulfonyloxy)-acetate, triarylsulfonium and diaryliodonium hexafluoroantimonates, hexafluoroarsenates, trifluoromethanesulfonates, iodonium perfluorooctanesulfonate, N-camphorsulfonyloxynaphthalimide, N-pentafluorophenylsulfonyloxynaphthalimide, ionic iodonium sulfonates such as diaryl iodonium (alkyl or aryl) sulfonate and bis-(dit-butylphenyl)iodonium camphanylsulfonate, perfluoroalkanesulfonates such as perfluoropentanesulfonate, perfluorooctanesulfonate, perfluoromethanesulfonate, aryl (e.g., phenyl or benzyl) triflates such as triphenylsulfonium triflate or bis-(t-butylphenyl)iodonium triflate; pyrogallol derivatives (e.g., trimesylate of pyrogallol), trifluoromethanesulfonate esters of hydroxyimides, α,α′-bis-sulfonyl-diazomethanes, sulfonate esters of nitro-substituted benzyl alcohols, naphthoquinone-4-diazides, alkyl disulfones, and the like.

In an embodiment in which the PACs are a free-radical generator, the PACs may comprise n-phenylglycine, aromatic ketones such as benzophenone, N,N'-tetramethyl-4,4'-diaminobenzophenone, N,N′-tetraethyl-4,4'-diaminobenzophenone, 4-methoxy-4'-dimethylaminobenzo- phenone, 3,3'-dimethyl-4-methoxybenzophenone, p,p′-bis(dimethylamino)benzo- phenone, p,p′-bis(diethylamino)-benzophenone, anthraquinone, 2-ethylanthraquinone, naphthaquinone and phenanthraquinone, benzoins such as benzoin, benzoinmethylether, benzoinethylether, benzoinisopropylether, benzoin-n-butylether, benzoin-phenylether, methylbenzoin and ethybenzoin, benzyl derivatives such as dibenzyl, benzyldiphenyldisulfide and benzyldimethylketal, acridine derivatives such as 9-phenylacridine and 1,7-bis(9-acridinyl)heptane, thioxanthones such as 2-chlorothioxanthone, 2-methylthioxanthone, 2,4-diethylthioxanthone, 2,4-dimethylthioxanthone and 2-isopropylthioxanthone, acetophenones such as 1,1-dichloroacetophenone, p-t-butyldichloro-acetophenone, 2,2-diethoxyacetophenone, 2,2-dimethoxy-2-phenylacetophenone, and 2,2-dichloro-4-phenoxyacetophenone, 2,4,5-triarylimidazole dimers such as 2-(o-chlorophenyl)-4,5-diphenylimidazole dimer, 2-(o-chlorophenyl)-4,5-di- (m-methoxyphenyl imidazole dimer, 2-(o-fluorophenyl)-4,5-diphenylimidazole dimer, 2-(o-methoxyphenyl)-4,5-diphenylimidazole dimer, 2-(p-methoxyphenyl)-4,5-diphenylimidazole dimer, 2,4-di(p-methoxyphenyl)-- 5-phenylimidazole dimer, 2-(2,4-dimethoxyphenyl)-4,5-diphenylimidazole dimer and 2-(p-methylmercaptophenyl)-4,5-diphenylimidazole dimmer, suitable combinations of these, or the like.

In an embodiment in which the PACs are a photobase generator, the PACs may comprise quaternary ammonium dithiocarbamates, α aminoketones, oxime-urethane containing molecules such as dibenzophenoneoxime hexamethylene diurethan, ammonium tetraorganylborate salts, and N-(2-nitrobenzyloxycarbonyl) cyclic amines, suitable combinations of these, or the like. However, as one of ordinary skill in the art will recognize, the chemical compounds listed herein are merely intended as illustrated examples of the PACs and are not intended to limit the embodiments to only those PACs specifically described. Rather, any suitable PAC may alternatively be utilized, and all such PACs are fully intended to be included within the scope of the present embodiments.

The individual components of the photoresist layer 148 may be placed into a photoresist solvent in order to aid in the mixing and placement of the photoresist layer 148. To aid in the mixing and placement of the photoresist layer 148, the photoresist solvent is chosen at least in part based upon the materials chosen for the photoresist polymer resin as well as the PACs. In particular, the photoresist solvent is chosen such that the photoresist polymer resin and the PACs can be evenly dissolved into the photoresist solvent and dispensed upon the carrier substrate 102 buildup.

In some embodiments, the photoresist solvent is a combination of solvents chosen for their chemical compatibility or similarity, their boiling point properties, and their hydrophilic/hydrophobic property. For example, a solvent mixture may contain a base solvent, one or more boiling point modifying solvents, and one or more hydrophilicity modifying solvents.

The base solvent acts as the main component of the photoresist solvent mixture and is selected to provide an acceptable baseline solvent performance and compatibility with the photoresist polymer resin and PACs. In some embodiments, the base solvent may also be selected to improve uneven surface coating uniformity. In an embodiment, the base solvent comprises at least 60% of the overall photoresist solvent mixture by atomic weight, such as 90%. Specific examples of base solvents include propylene glycol monomethyl ether acetate (PGMEA), methyl amyl ketone (MAK), n-butyl acetate, and the like. However, any suitable base solvents may be utilized.

The one or more boiling point modifying solvents act to modify the overall boiling point of the photoresist solvent mixture and are selected based on their chemical compatibility with the base solvent. In an embodiment, the boiling point modifying solvents have higher boiling points (e.g., a boiling point that is at least 20° C. higher than the boiling point of the base solvent) than the base solvent and comprise between 5% and 40% of the overall photoresist solvent mixture by atomic weight, such at 9.5%. In embodiments where the boiling point modifying solvent has a higher boiling point than the base solvent, the overall boiling point of the photoresist solvent mixture is raised. Specific examples of base solvents include 3-methoxy butyl acetate (MBA), ethoxy ethyl propionate (EEP), propylene glycol diacetate (PGDA), and the like.

The one or more hydrophilicity modifying solvents acts to modify the overall hydrophobic or hydrophilic tendencies of the photoresist solvent mixture. In an embodiment, the hydrophilicity modifying solvents have more hydrophilic tendencies than the base solvent and/or the one or more boiling point modifying solvents. In an embodiment the hydrophilicity modifying solvents comprise between 0.1% and 5% of the overall photoresist solvent mixture by atomic weight, such as 0.5%. In embodiments where the hydrophilicity modifying solvents have more hydrophilic tendencies than the base solvent and/or the one or more boiling point modifying solvents, the hydrophilicity modifying solvents act to counteract and mitigate the hydrophobic nature of the overall photoresist solvent mixture (where the overall mixture tends hydrophobic due to the base solvent and/or boiling point modifying solvents chemical properties). Specific examples of hydrophilicity modifying solvents include gamma-butyrolactone (GBL), n-methyl pyrrolidone (NMP), dimethylacetamide (DMAC), and the like.

In one particular embodiment the photoresist solvent mixture is a combination of PGMEA, MBA, and GBL. In such a combination PGMEA is used as the base solvent. MBA, having a higher boiling point than PGMEA, is added to increase the boiling point of the mixture, and because of the chemical similarity between MBA and PGMEA. GBL, which is highly hydrophilic and has a higher boiling point than PGMEA, is added to decrease the hydrophobic properties of the mixture while maintaining and/or further raising the boiling point of the overall solvent mixture. In an embodiment, PGMEA comprises 90% of the overall photoresist solvent mixture by atomic weight, MBA comprises 9.5% of the overall photoresist solvent mixture by atomic weight, and GBL comprises 0.5% of the overall photoresist solvent mixture by atomic weight. This can be referred to as a 90/9.5/0 PGMEA/MBA/GBL photoresist solvent mixture.

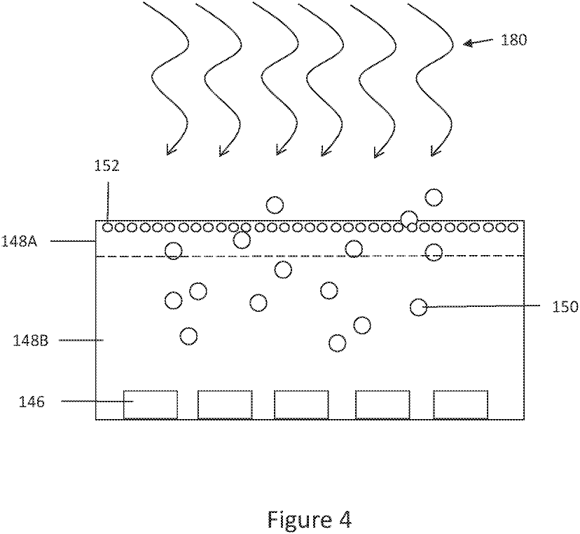

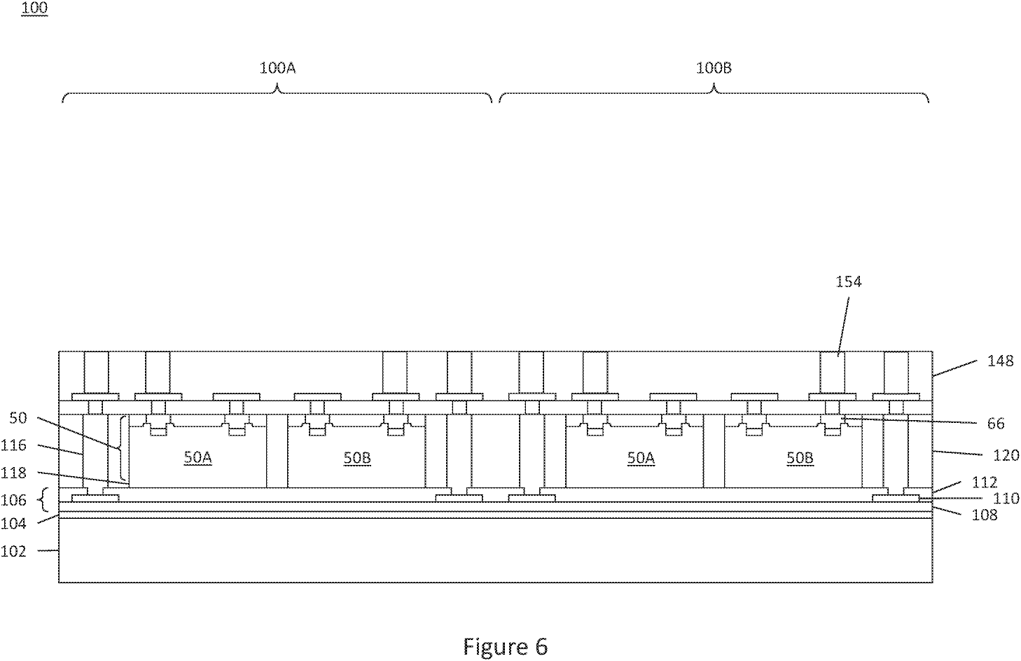

By increasing the boiling point of the solvent mixture, such as by using a 90/9.5/0 PGMEA/MBA/GBL photoresist solvent mixture, as well as selecting a pre-bake 180 (see FIG. 4) temperature below the boiling point of the solvent mixture (discussed later in relation to FIG. 4), the photoresist solvent evaporation rate can be slowed. Slowing the evaporation rate of the photoresist solvent provides more time for the bubbles 150 (see FIG. 3) to migrate out of the photoresist layer 148 prior to patterning. Accordingly, fewer defects can be realized in the photoresist layer 148 and the associated through vias 154 (see FIG. 6) patterned by the photoresist layer 148.

As one of ordinary skill in the art will recognize, the materials listed and described above as examples of materials that may be utilized for the photoresist solvent component of the photoresist layer 148 are merely illustrative and are not intended to limit the embodiments. Rather, any suitable material that may dissolve the photoresist polymer resin and the PACs may alternatively be utilized as the base solvent to help mix and apply the photoresist layer 148. Other combinations of high boiling point solvents and hydrophilic tending solvents, in conjunction with the base solvent, may be utilized to create solvent mixtures beyond those disclosed herein. All such materials are fully intended to be included within the scope of the embodiments.

In some embodiments, a photoresist cross-linking agent may also be added to the photoresist layer 148. The photoresist cross-linking agent reacts with the photoresist polymer resin within the photoresist layer 148 after exposure, assisting in increasing the cross-linking density of the photoresist, which helps to improve the resist pattern and resistance to dry etching. In an embodiment the photoresist cross-linking agent may be a melamine based agent, a urea based agent, ethylene urea based agent, propylene urea based agent, glycoluril based agent, an aliphatic cyclic hydrocarbon having a hydroxyl group, a hydroxyalkyl group, or a combination of these, oxygen containing derivatives of the aliphatic cyclic hydrocarbon, glycoluril compounds, etherified amino resins, combinations of these, or the like.

Specific examples of materials that may be utilized as a photoresist cross-linking agent include melamine, acetoguanamine, benzoguanamine, urea, ethylene urea, or glycoluril with formaldehyde, glycoluril with a combination of formaldehyde and a lower alcohol, hexamethoxymethylmelamine, bismethoxymethylurea, bismethoxymethylbismethoxyethylene urea, tetramethoxymethylglycoluril, and tetrabutoxymethylglycoluril, mono-, di-, tri-, or tetra-hydroxymethylated glycoluril, mono-, di-, tri-, and/or tetra-methoxymethylated glycoluril, mono-, di-, tri-, and/or tetra-ethoxymethylated glycoluril, mono-, di-, tri-, and/or tetra-propoxymethylated glycoluril, and mono-, di-, tri-, and/or tetra-butoxymethylated glycoluril, 2,3-dihydroxy-5-hydroxymethylnorbornane, 2-hydroy-5,6-bis(hydroxymethyl)norbornane, cyclohexanedimethanol, 3,4,8(or 9)-trihydroxytricyclodecane, 2-methyl-2-adamantanol, 1,4-dioxane-2,3-diol and 1,3,5-trihydroxycyclohexane, tetramethoxymethyl glycoluril, methylpropyltetramethoxymethyl glycoluril, and methylphenyltetramethoxymethylglycoluril, 2,6-bis(hydroxymethyl)p-cresol, N-methoxymethyl- or N-butoxymethyl-melamine. Additionally, compounds obtained by reacting formaldehyde, or formaldehyde and lower alcohols with amino group-containing compounds, such as melamine, acetoguanamine, benzoguanamine, urea, ethylene urea and glycoluril, and substituting the hydrogen atoms of the amino group with hydroxymethyl group or lower alkoxymethyl group, examples being hexamethoxymethylmelamine, bismethoxymethyl urea, bismethoxymethylbismethoxyethylene urea, tetramethoxymethyl glycoluril and tetrabutoxymethyl glycoluril, copolymers of 3-chloro-2-hydroxypropyl methacrylate and methacrylic acid, copolymers of 3-chloro-2-hydroxypropyl methacrylate and cyclohexyl methacrylate and methacrylic acid, copolymers of 3-chloro-2-hydroxypropyl methacrylate and benzyl methacrylate and methacrylic acid, bisphenol A-di(3-chloro-2-hydroxypropyl)ether, poly(3-chloro-2-hydroxypro- pyl)ether of a phenol novolak resin, pentaerythritol tetra(3-chloro-2-hydroxypropyl)ether, trimethylolmethane tri(3-chloro-2-hydroxypropyl)ether phenol, bisphenol A-di(3-acetoxy-2-hydroxypropyl)ether, poly(3-acetoxy-2-hydroxypropyl)ether of a phenol novolak resin, pentaerythritol tetra(3-acetoxy-2-hydroxypropyl)ether, pentaerythritol poly(3-chloroacetoxy-2-hydroxypropyl)ether, trimethylolmethane tri(3-acetoxy-2-hydroxypropyl)ether, combinations of these, or the like.

In some embodiments, the cross-linking agent comprises a floating cross-linking agent. The floating cross-linking agent will react with the polymers within the polymer resin and form linear or branched polymers structure that have larger molecular weight molecules, thereby improving the cross-linking density. In an embodiment the floating cross-linking agent may be an aliphatic polyether such as a polyether polyol, a polyglycidy ether, a vinyl ether, a glycouril, a triazene, combinations of these, or the like.

In an embodiment the floating cross-linking agent also comprises a substituted fluorine atom that has been incorporated into the structure of the floating cross-linking agent. In a particular embodiment the fluorine atom may be incorporated into the cross-linking structure as one or more fluorine atoms substituted for, e.g., a hydrogen atom within an alkyl group located within the structure of the floating cross-linking agent.

Alternatively, the fluorine atom may be part of an alkyl fluoride group that is substituted into the structure of the floating cross-linking agent. The fluorine atom may be incorporated into an alkyl fluoride group with any suitable number of carbon and fluorine atoms. As one of ordinary skill in the art will recognize, the examples listed above regarding the structures and groups that may be used within the floating cross-linking agent are merely intended to be illustrative and are not intended to list every possible structure or groups that may be utilized to form the floating cross-linking agent. Any suitable alternative structures and any suitable alternative groups may be utilized to form the floating cross-linking agent. All such structures and groups are fully intended to be included within the scope of the embodiments.

In addition to the photoresist polymer resins, the PACs, the photoresist solvents, and the photoresist cross-linking agents, the photoresist layer 148 may also include a number of other additives that will assist the photoresist layer 148 obtain the highest resolution. For example, the photoresist layer 148 may also include surfactants 152 in order to help improve the ability of the photoresist layer 148 to coat the surface on which it is applied. In an embodiment the surfactants 152 may include nonionic surfactants 152, polymers having fluorinated aliphatic groups, surfactants 152 that contain at least one fluorine atom and/or at least one silicon atom, polyoxyethylene alkyl ethers, polyoxyethylene alkyl aryl ethers, polyoxyethylene-polyoxypropylene block copolymers, sorbitan fatty acid esters, polyoxyethylene sorbitan fatty acid esters.

In one particular embodiment the surfactant 152 may be a four carbon (C4) chain block oligomer that is richly hydrophobic and is also compatible with PGMEA/MBA/GBL solvent mixtures. For example, the surfactant 152 may be a surfactant 152 such as organo-hydrosiloxane polymer, hydrocarbon surfactant product, fluorotelomer-based polymer, combinations of these, or the like. The use of such a surfactant 152 reduces the total amount of surfactant 152 used in the photoresist mixture, while still providing a similar coating capability. For example, in a very particular case in which the surfactant is a fluoro-acrylated block copolymer, the surfactant may be perfluorohexylethyl methacrylate copolymer (CAS# 1557087-30-5), and the amount of surfactant 152 used in the photoresist mixture can be reduced to a concentration of 1 part per million (ppm) to 20 ppm. Utilizing the lower surfactant 152 concentration allows more bubbles 150 to pass through the air/liquid interface, thereby removing more bubbles that can cause defects.

Another additive that may be added to the photoresist layer 148 is a quencher, which may be utilized to inhibit diffusion of the generated acids/bases/free radicals within the photoresist, which helps the resist pattern configuration as well as to improve the stability of the photoresist layer 148 over time. In an embodiment the quencher is an amine such as a second lower aliphatic amine, a tertiary lower aliphatic amine, or the like. Specific examples of amines that may be used include trimethylamine, diethylamine, triethylamine, di-n-propylamine, tri-n-propylamine, tripentylamine, diethanolamine, and triethanolamine, alkanolamine, combinations of these, or the like.

Alternatively, an organic acid may be utilized as the quencher. Specific embodiments of organic acids that may be utilized include malonic acid, citric acid, malic acid, succinic acid, benzoic acid, salicylic acid, phosphorous oxo acid and its derivatives such as phosphoric acid and derivatives thereof such as its esters, such as phosphoric acid, phosphoric acid di-n-butyl ester and phosphoric acid diphenyl ester; phosphonic acid and derivatives thereof such as its ester, such as phosphonic acid, phosphonic acid dimethyl ester, phosphonic acid di-n-butyl ester, phenylphosphonic acid, phosphonic acid diphenyl ester, and phosphonic acid dibenzyl ester; and phosphinic acid and derivatives thereof such as its esters, including phosphinic acid and phenylphosphinic acid.

Another additive that may be added to the photoresist layer 148 is a stabilizer, which assists in preventing undesired diffusion of the acids generated during exposure of the photoresist layer 148. In an embodiment the stabilizer may include nitrogenous compounds such as aliphatic primary, secondary, and tertiary amines, cyclic amines such as piperidines, pyrrolidines, morpholines, aromatic heterocycles such as pyridines, pyrimidines, purines, imines such as diazabicycloundecene, guanidines, imides, amides, and others. Alternatively, ammonium salts may also be used for the stabilizer, including ammonium, primary, secondary, tertiary, and quaternary alkyl- and arylammonium salts of alkoxides including hydroxide, phenolates, carboxylates, aryl and alkyl sulfonates, sulfonamides, and others. Other cationic nitrogenous compounds including pyridinium salts and salts of other heterocyclic nitrogenous compounds with anions such as alkoxides including hydroxide, phenolates, carboxylates, aryl and alkyl sulfonates, sulfonamides, and the like may also be employed.

Yet another additive that may be added to the photoresist layer 148 may be a dissolution inhibitor in order to help control dissolution of the photoresist layer 148 during development. In an embodiment bile-salt esters may be utilized as the dissolution inhibitor. Specific examples of materials that may be utilized include cholic acid (IV), deoxycholic acid (V), lithocholic acid (VI), t-butyl deoxycholate (VII), t-butyl lithocholate (VIII), and t-butyl-3-α-acetyl lithocholate (IX).

Another additive that may be added to the photoresist layer 148 may be a plasticizer. Plasticizers may be used to reduce delamination and cracking between the photoresist layer 148 and underlying layers and may comprise monomeric, oligomeric, and polymeric plasticizers such as oligo- and polyethyleneglycol ethers, cycloaliphatic esters, and non-acid reactive steroidally-derived materials. Specific examples of materials that may be used for the plasticizer include dioctyl phthalate, didodecyl phthalate, triethylene glycol dicaprylate, dimethyl glycol phthalate, tricresyl phosphate, dioctyl adipate, dibutyl sebacate, triacetyl glycerine and the like.

Yet another additive that may be added include a coloring agent, which helps observers examine the photoresist layer 148 and find any defects that may need to be remedied prior to further processing. In an embodiment the coloring agent may be either a triarylmethane dye or, alternatively, may be a fine particle organic pigment. Specific examples of materials that may be used as coloring agents include crystal violet, methyl violet, ethyl violet, oil blue #603, Victoria Pure Blue BOH, malachite green, diamond green, phthalocyanine pigments, azo pigments, carbon black, titanium oxide, brilliant green dye (C. I. 42020), Victoria Pure Blue FGA (Linebrow), Victoria BO (Linebrow) (C. I. 42595), Victoria Blue BO (C. I. 44045) rhodamine 6G (C. I. 45160), Benzophenone compounds such as 2,4-dihydroxybenzophenone and 2,2',4,4'-tetrahydroxybenzophenone, salicylic acid compounds such as phenyl salicylate and 4-t-butylphenyl salicylate, phenylacrylate compounds such as ethyl-2-cyano-3,3-diphenylacrylate, and 2'-ethylhexyl-2-cyano-3,3-diphenylacrylate, benzotriazole compounds such as 2-(2-hydroxy-5-methylphenyl)-2H-benzotriazole, and 2-(3-t-butyl-2-hydroxy-5-methylphenyl)-5-chloro-2H-benzotriazole, coumarin compounds such as 4-methyl-7-diethylamino-1-benzopyran-2-one, thioxanthone compounds such as diethylthioxanthone, stilbene compounds, naphthalic acid compounds, azo dyes, Phthalocyanine blue, phthalocyanine green, iodine green, Victoria blue, naphthalene black, Photopia methyl violet, bromphenol blue and bromcresol green, laser dyes such as Rhodamine G6, Coumarin 500, DCM (4-(dicyanomethylene)-2-methyl-6-(4-dimethylaminostyryl)-4H pyran)), Kiton Red 620, Pyrromethene 580, or the like. Additionally, one or more coloring agents may be used in combination to provide the desired coloring.

Adhesion additives may also be added to the photoresist layer 148 in order to promote adhesion between the photoresist layer 148 and an underlying layer upon which the photoresist layer 148 has been applied. In an embodiment the adhesion additives include a silane compound with at least one reactive substituent such as a carboxyl group, a methacryloyl group, an isocyanate group and/or an epoxy group. Specific examples of the adhesion components include trimethoxysilyl benzoic acid, γ-methacryloxypropyl trimethoxy silane, vinyltriacetoxysilane, vinyltrimethoxysilane, γ-isocyanatepropyl triethoxy silane, γ-glycidoxypropyl trimethoxy silane, β-(3,4-epoxycyclohexyl)ethyl trimethoxy silane, benzimidazoles and polybenzimidazoles, a lower hydroxyalkyl substituted pyridine derivative, a nitrogen heterocyclic compound, urea, thiourea, 8-oxyquinoline, 4-hydroxypteridine and derivatives, 1,10-phenanthroline and derivatives, 2,2'-bipyridine and derivatives, benzotriazoles; organophosphorus compounds, phenylenediamine compounds, 2-amino-1-phenylethanol, N-phenylethanolamine, N-ethyldiethanolamine, N-ethylethanolamine and derivatives, benzothiazole, and a benzothiazoleamine salt having a cyclohexyl ring and a morpholine ring, 3-glycidoxypropyltrimethoxysilane, 3-glycidoxypropyltriethoxysilane, 3-mercaptopropyltrimethoxysilane, 3-mercaptopropyltriethoxysilane, 3-methacryloyloxypropyltrimethoxysilane, vinyl trimethoxysilane, combinations of these, or the like.

Surface leveling agents may additionally be added to the photoresist layer 148 in order to assist a top surface of the photoresist layer 148 to be level so that impinging light will not be adversely modified by an unlevel surface. In an embodiment surface leveling agents may include fluoroaliphatic esters, hydroxyl terminated fluorinated polyethers, fluorinated ethylene glycol polymers, silicones, acrylic polymer leveling agents, combinations of these, or the like.

In an embodiment the photoresist polymer resin and the PACs, along with any desired additives or other agents, are added to the photoresist solvent for application. Once added, the mixture is then mixed in order to achieve an even composition throughout the photoresist layer 148 in order to ensure that there are no defects caused by an uneven mixing or non-constant composition of the photoresist layer 148. Once mixed together, the photoresist layer 148 may either be stored prior to its usage or else used immediately.

Once ready, the photoresist layer 148 may be utilized by initially applying the photoresist layer 148 onto the carrier substrate 102, coating the seed layer applied over the UBMLs 146 and dielectric 144. The photoresist layer 148 may be applied using a process such as a spin-on coating process, a dip coating method, an air-knife coating method, a curtain coating method, a wire-bar coating method, a gravure coating method, combinations of these, or the like. In an embodiment the photoresist layer 148 may be applied such that it has a thickness over the surface of the seed layer of between about 150 nm and about 250 nm, such as about 350 nm.

FIG. 3 further illustrates the floating cross-linker and surfactant 152 forming a floating region 148A along a top surface of the photoresist layer 148 (comprising the floating region 148A and bulk photoresist region 148B). During deposition, the floating cross-linker and surfactant 152 will move to the top of the photoresist layer 148 as the photoresist layer is being applied, e.g., in the spin-on process. This movement of the floating cross-linker is initiated because the addition of the fluorine atom causes the floating cross-linker to have a high surface energy. This high surface energy, coupled with the low interaction between the fluorine atoms and the other atoms within the photoresist layer 148, will initiate the movement of the floating cross-linker to the top surface of the photoresist layer 148 as shown in FIG. 3.

Due to the movement of the floating cross-linker, the floating region 148A will have a higher concentration of the floating cross-linker than a remainder of the photoresist layer 148, such as by having a concentration of between about 0.01% and about 10%, such as about 2%, while the remainder of the photoresist layer 148, comprising the bulk photoresist region 148B (outside of the floating region 148A) will have a concentration of the floating cross-linker 152 no greater than about 5%. Additionally, the floating region 148A will have a thickness Ti of less than about 50% of the overall thickness of the photoresist layer 148, such as between about 100 angstrom (Å) and about 300 Å, such as about 200 Å. However, these dimensions and concentrations may vary and are intended to be illustrative only, and any benefits may be derived from suitable concentrations different from those listed herein.

Similarly, in some embodiments, due to the surface affinity of the surfactant 152, the surfactant 152 will also migrate into the floating region 148A. Accordingly, the floating region 148A will also have a higher concentration of the surfactant 152 than the remainder of the photoresist layer 148, particular at the air/photoresist mixture interface, such as by having a concentration of between 1 ppm and 20 ppm, such as about 10 ppm, and no more than 20 ppm, while the remainder of the photoresist layer 148, comprising the bulk photoresist region 148B (outside of the floating region 148A) will have a concentration of the surfactant 152 no greater than about 20 ppm. It has been shown that by maintaining a surfactant 152 concentration in the photoresist mixture between 5 ppm and 20 ppm, bubble formation at the surface can be reduced or eliminated due to the resulting change in surface tension from a reduced surfactant 152 loading.

As shown in FIG. 4, once the photoresist layer 148 has been applied to the semiconductor substrate, a pre-bake 180 of the photoresist layer 148 is performed in order to cure and dry the photoresist layer 148 prior to exposure to finish the application of the photoresist layer 148. The curing and drying of the photoresist layer 148 removes the photoresist solvent component while leaving behind the photoresist polymer resin, the PACs, photoresist cross-linking agents, and the other chosen additives.

In an embodiment the pre-bake 180 may be performed at a temperature suitable to evaporate the photoresist solvent, such as between about 100° C. and 130° C., such as 120° C., although the precise temperature depends upon the materials chosen for the photoresist layer 148. The pre-bake 180 is performed for a time sufficient to cure and dry the photoresist layer 148, allowing the solvent mixture to evaporate and any trapped bubbles 150 to migrate out of the photoresist layer 148, such as between about 300 seconds to about 10 minutes, such as about 420 seconds.

However, the curing process described above (in which a thermal bake is performed to cure the photoresist layer 148), is merely one illustrative process that may be used to cure the photoresist layer 148 and initiate the cross-linking reactions, and is not intended to limit the embodiments. Rather, any suitable curing process, such as exposing the photoresist layer 148 to an energy source (e.g., a photolithography exposure with a wavelength between about 10 nm to about 1000 nm), irradiating the photoresist layer 148 to cure the photoresist layer 148, or even an electrical cure of the photoresist layer 148, may alternatively be utilized. All such curing processes are fully intended to be included within the scope of the embodiments.

By using a higher boiling point solvent mixture with less hydrophobic tendencies, such as the 90/9.5/0 PGMEA/MBA/GBL photoresist solvent mixture discussed above, the solvent evaporation rate during the pre-bake 180 is slowed, allowing for a reduction in trapped gasses remaining in the bulk of the photoresist layer 148. Further, through the use of a floating cross-linker 152 and a surfactant 152 with higher hydrophilic properties and fluorine concentrations, lower surfactant 152 concentrations can be utilized in the photoresist mixture, and, as such, less of the surfactant 152 is present to trap the bubbles 150, and the bubbles 150 are more easily allowed to migrate though the floating region 148A and out of the photoresist layer during deposition and the pre-bake 180 process. Accordingly, an overall more level photoresist layer 148, substantially free of internal and surface defects caused by trapped bubbles 150, can be realized. In some embodiments, the surface of the photoresist layer is substantially level after using the processes described above, and a resulting height variability across the photoresist layer 148 is limited to between 100 Å and 300 Å.

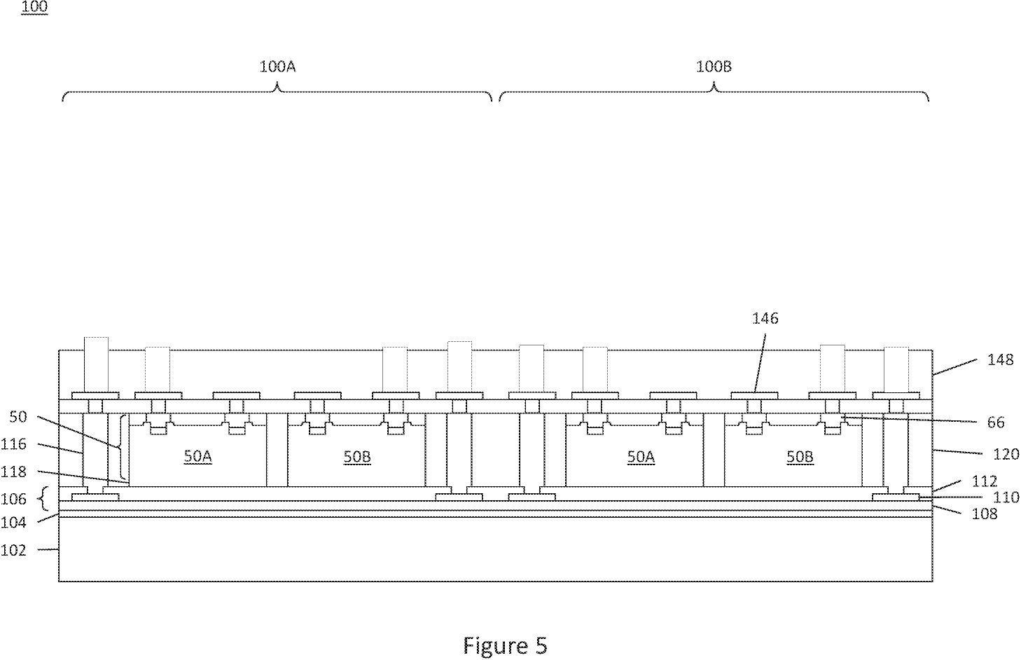

In FIG. 5, the photoresist layer 148, once cured and dried, may be patterned by placing the carrier substrate 102 and the photoresist layer 148 in a photoresist imaging device (not shown) for exposure. The photoresist imaging device supplies photoresist energy, such as light, to portions of the photoresist layer 148 controlled by a pattern mask located between the photoresist energy supply and the photoresist layer 148, in order to induce a reaction of the PACs, which in turn reacts with the photoresist polymer resin to chemically alter those portions of the photoresist layer 148 to which the photoresist energy impinges, and that are not blocked by the pattern mask.

For example, in an embodiment in which the patterned energy is a 193 nm wavelength of light, the PAC is a photoacid generator, and the group to be decomposed is a carboxylic acid group on the hydrocarbon structure and a cross linking agent is used, the patterned energy will impinge upon the photoacid generator and the photoacid generator will absorb the impinging patterned energy. This absorption initiates the photoacid generator to generate a proton (e.g., a H⁺ ion) within the photoresist layer 148. When the proton impacts the carboxylic acid group on the hydrocarbon structure, the proton will react with the carboxylic acid group, chemically altering the carboxylic acid group and altering the properties of the photoresist polymer resin in general. The carboxylic acid group will then react with the photoresist cross-linking agent to crosslink with other photoresist polymer resins within the photoresist layer 148.

After the photoresist layer 148 has been exposed to the patterned energy, a post-exposure baking may be used in order to assist in the generating, dispersing, and reacting of the acid/base/free radical generated from the impingement of the patterned energy upon the PACs during the exposure. Such assistance helps to create or enhance chemical reactions which generate chemical differences between the exposed regions and the unexposed regions within the photoresist layer 148. These chemical differences also cause differences in the solubility between the exposed regions and the unexposed regions. In an embodiment this post-exposure baking may occur at temperatures of between about 50° C. and about 160° C. for a period of between about 40 seconds and about 120 seconds.

After the photoresist layer 148 has been exposed and the post-exposure baking has occurred, the photoresist layer 148 may be developed using either a positive tone developer or a negative tone developer, depending upon the desired pattern for the photoresist layer 148. In an embodiment in which the exposed regions of the photoresist layer 148 is desired to be removed to form a positive tone, a positive tone developer such as a basic aqueous solution may be utilized to remove those portions of the photoresist layer 148 which were exposed to the patterned energy and which have had their solubility modified and changed through the chemical reactions. Such basic aqueous solutions may include tetra methyl ammonium hydroxide (TMAH), tetra butyl ammonium hydroxide, sodium hydroxide, potassium hydroxide, sodium carbonate, sodium bicarbonate, sodium silicate, sodium metasilicate, aqueous ammonia, monomethylamine, dimethylamine, trimethylamine, monoethylamine, diethylamine, triethylamine, monoisopropylamine, diisopropylamine, triisopropylamine, monobutylamine, dibutylamine, monoethanolamine, diethanolamine, triethanolamine, dimethylaminoethanol, diethylaminoethanol, potassium metasilicate, sodium carbonate, tetraethylammonium hydroxide, combinations of these, or the like.

If a negative tone development is desired, an organic solvent or critical fluid may be utilized to remove those portions of the photoresist layer 148 which were not exposed to the energy and, as such, retain their original solubility. Specific examples of materials that may be utilized include hydrocarbon solvents, alcohol solvents, ether solvents, ester solvents, critical fluids, combinations of these, or the like. Specific examples of materials that can be used for the negative tone solvent include hexane, heptane, octane, toluene, xylene, dichloromethane, chloroform, carbon tetrachloride, trichloroethylene, methanol, ethanol, propanol, butanol, critical carbon dioxide, diethyl ether, dipropyl ether, dibutyl ether, ethyl vinyl ether, dioxane, propylene oxide, tetrahydrofuran, cellosolve, methyl cellosolve, butyl cellosolve, methyl carbitol, diethylene glycol monoethyl ether, acetone, methyl ethyl ketone, methyl isobutyl ketone, isophorone, cyclohexanone, methyl acetate, ethyl acetate, propyl acetate, butyl acetate, pyridine, formamide, N,N-dimethyl formamide, or the like.

However, as one of ordinary skill in the art will recognize, the above description of positive tone developers and negative tone developers are only intended to be illustrative and are not intended to limit the embodiments to only the developers listed above. Rather, any suitable type of developer, including acid developers or even water developers, that may be utilized to selectively remove a portion of the photoresist layer 148 that has a different property (e.g., solubility) than another portion of the photoresist layer 148, may alternatively be utilized, and all such developers are fully intended to be included within the scope of the embodiments.

In FIG. 6, a conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the through vias 154.

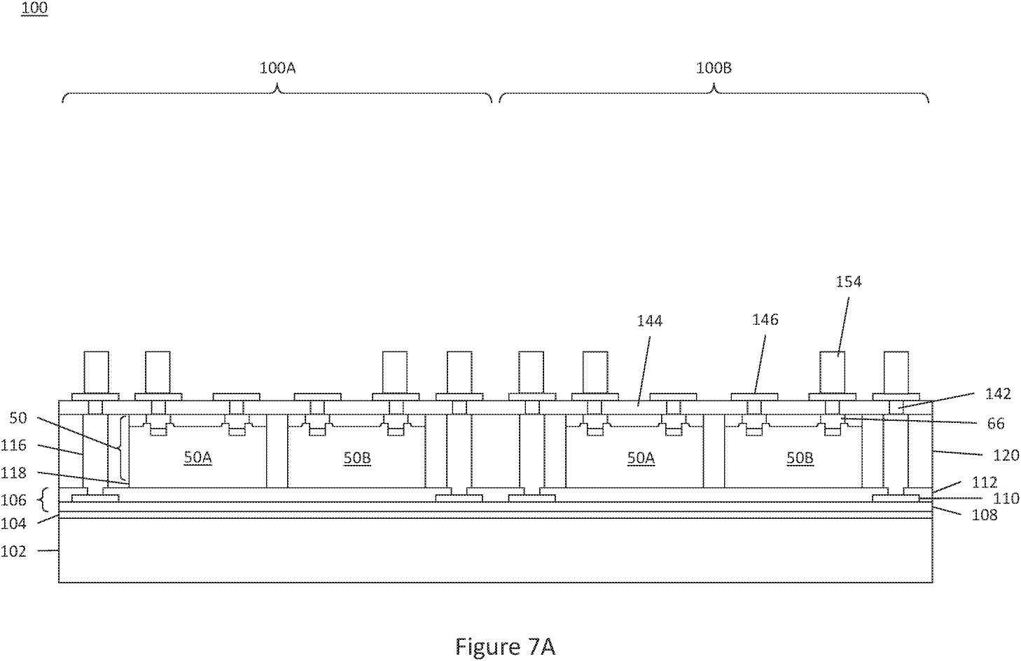

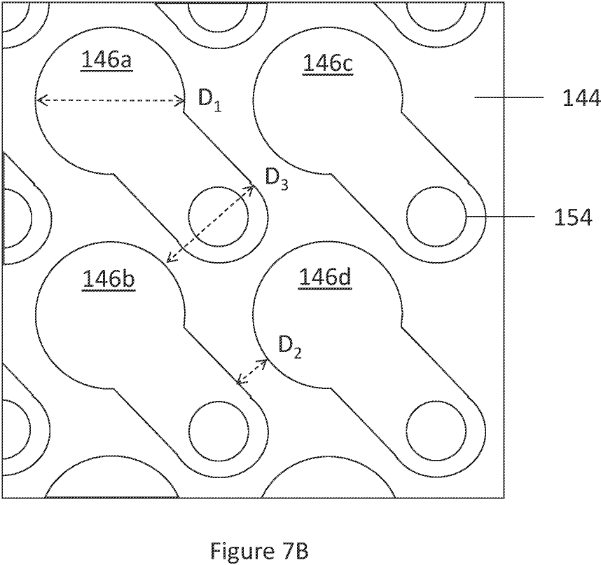

FIG. 7A illustrates the removal of the photoresist layer 148. In an embodiment the photoresist layer 148 may be removed using, e.g., an ashing process, whereby the temperature of the photoresist layer 148 is increased until the photoresist layer 148 undergoes a thermal decomposition. Once thermally decomposed, the photoresist layer 148 may be physically removed using one or more wash processes.

FIG. 7B illustrates a top down view of a particular embodiment of a layout of the through vias 154 over the UBMLs 146. In the illustrated embodiment, the UBMLs 146 may be formed such that there is an elongated portion on which the through vias 154 are formed and a lobe portion which is formed over the conductive vias 142 (see FIG. 7A). In some embodiments, the lobe portion of the UBMLs has a first diameter D₁ ranging from 30 µm to 70 µm, such as 62 µm. Additionally, the UBMLs 146 may be spaced such that a distance D₂ from a closest edge of a UBML 146 (e.g., UBML 146b in the embodiment shown in FIG. 7B) to the closest portion of an adjacent UBML 146 (e.g., UBML 146d) may be from 15 µm to 50 µm, such as 39 µm, and a span distance D₃ from the closest edge of an adjacent UBML 146 (e.g., UBML 146b) to the furthest point of the UBML 146a, opposite a line perpendicular to the tangent of a lobe portion of the adjacent UBML 146b, has a range from 25 µm to 70 µm, such as 39 µm. However, any suitable dimensions and layouts may be utilized.

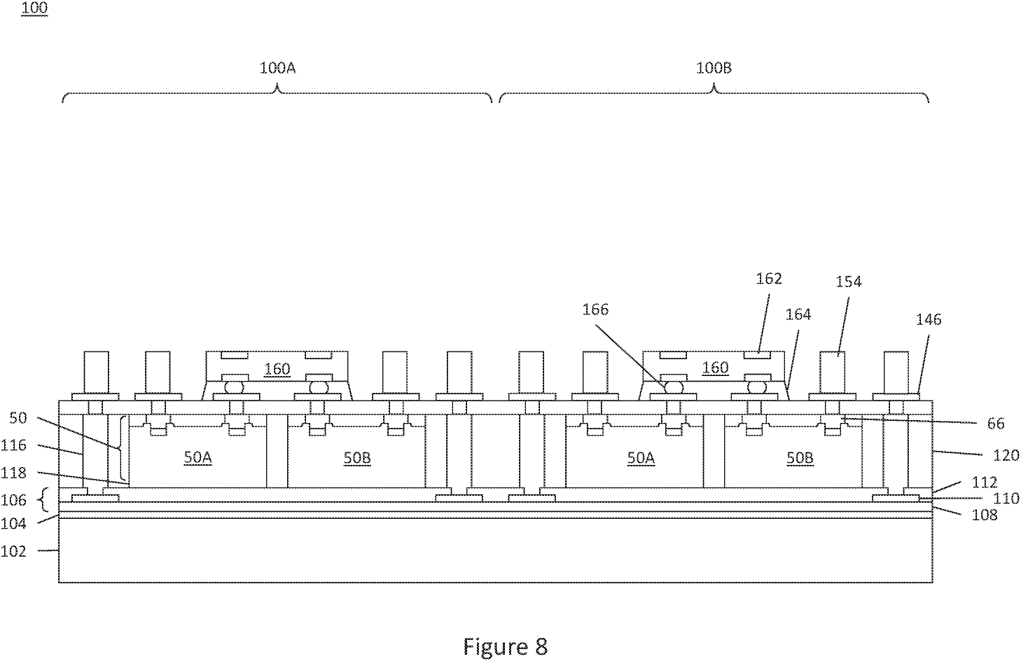

In FIG. 8, integrated component packages 160, such as large scale integration (LSI) packages, are attached to the integrated circuit package 100 through utilizing front and/or back-side die connectors 162 included in the integrated component packages 160. The integrated component packages 160 may include electronic components and/or memory devices (e.g., memory chips or memory packages). In some embodiment, the integrated component packages 160 may include a central processing unit (CPU), field programmable gate array (FPGA), microcontrollers, and the like. In some embodiment, the electronic components may be memory devices such as high bandwidth memories (HBM), dynamic random access memories (DRAM), static random access memories (SRAM) and the combination thereof. In some alternative embodiments, the electronic components may be a graphical processing unit (GPU) chip, power management dies (e.g., power management integrated circuit (PMIC) dies), radio frequency (RF) dies, sensor dies, micro-electro-mechanical-system (MEMS) dies, signal processing dies (e.g., digital signal processing (DSP) dies), front-end dies (e.g., analog front-end (AFE) dies), the like, or a combination thereof. In some alternative embodiments, the electronic components may also be passive components (e.g., resistors, inductors, capacitors, etc.). In some embodiments, the electronic components may be a combination of any of the above-mentioned candidates.

In some embodiments, conductive connectors 166 are formed on either the UBMLs 146 or the integrated component packages 160. The conductive connectors 166 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 166 may include a conductive material such as solder, copper, aluminum, gold, nickel, silver, palladium, tin, the like, or a combination thereof. In some embodiments, the conductive connectors 166 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 166 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

The integrated component packages 160 are then attached to the integrated circuit package 100 using the conductive connectors 166. Attaching the integrated component packages 160 may include placing the integrated component packages 160 and reflowing the conductive connectors 166 to physically and electrically couple the integrated component packages 160 and to the underlying UBMLs 146.

In some embodiments, an underfill 164 is placed surrounding the conductive connectors 166. The underfill 164 may reduce stress and protect the joints resulting from the reflowing of the conductive connectors 166. The underfill 164 may also be included to securely bond the integrated component packages 160 to the integrated circuit package 100 and provide structural support and environmental protection. The underfill 164 may be formed by a capillary flow process after the integrated component packages 160 are attached, or may be formed by a suitable deposition method before the integrated component packages 160 are attached. The underfill 164 may be formed of a molding compound, epoxy, or the like, and may be applied by injection molding, transfer molding, or the like. The underfill 164 may be applied in liquid or semi-liquid form and then subsequently cured.

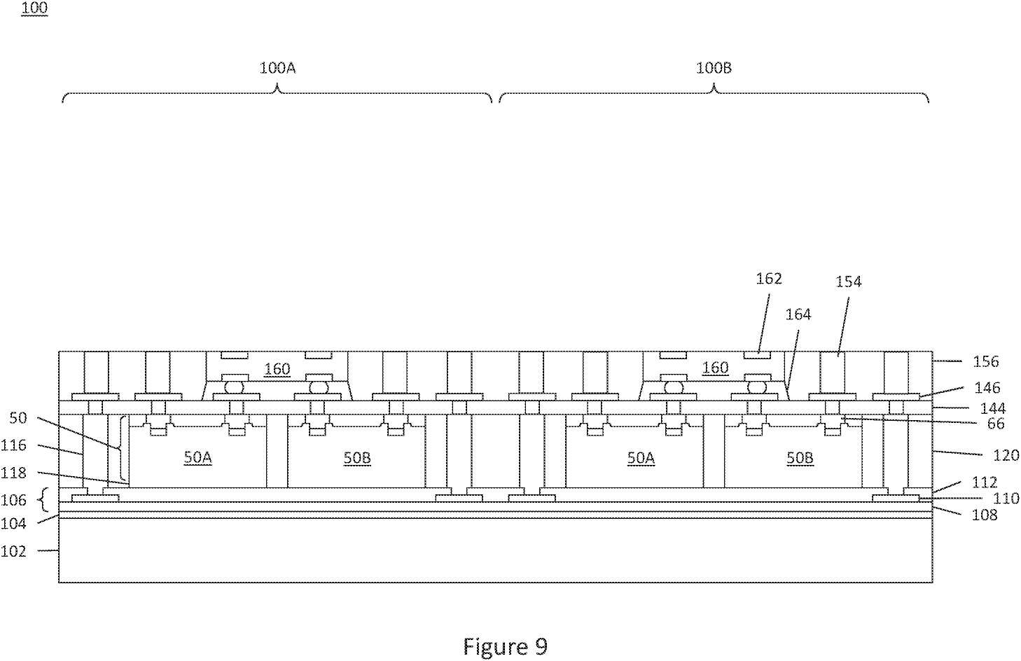

In FIG. 9, an encapsulant 156 is formed on and around the various components. After formation, the encapsulant 156 surrounds the integrated component packages 160, through vias 154, UBMLs 146, underfill 164, and the top of the dielectric 144. The encapsulant 156 may be formed of a molding compound, epoxy, or the like, and may be applied by compression molding, transfer molding, or the like. The encapsulant 156 may be applied in liquid or semi-liquid form and then subsequently cured. The encapsulant 156 may be formed over the carrier substrate 102 such that the through vias 154 and integrated component packages 160 are buried or covered.

In some embodiments, a planarization process may be performed on the encapsulant 156 to expose the through vias 154 and die connectors 162 of the integrated component packages 160. Topmost surfaces of the encapsulant 156, through vias 154, and die connectors 162 are substantially level (e.g., planar) after the planarization process within process variations. The planarization process may be, for example, a chemical-mechanical polish (CMP), a grinding process, or the like. In some embodiments, the planarization may be omitted, for example, if the through vias 154 and die connectors 162 are already exposed. Other processes may be used to achieve a similar result.

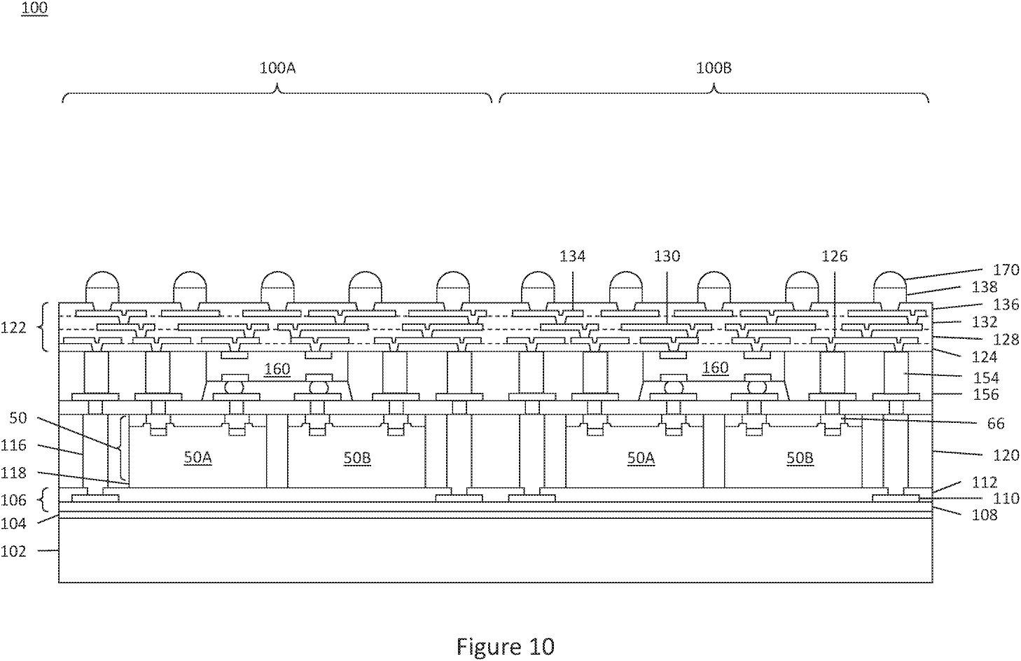

In FIG. 10, a front-side redistribution structure 122 is formed over the encapsulant 156, through vias 154, and integrated component packages 160. The front-side redistribution structure 122 includes dielectric layers 124, 128, 132, and 136; and metallization patterns 126, 130, and 134. The metallization patterns may also be referred to as redistribution layers or redistribution lines. The front-side redistribution structure 122 is shown as an example having three layers of metallization patterns. More or fewer dielectric layers and metallization patterns may be formed in the front-side redistribution structure 122. If fewer dielectric layers and metallization patterns are to be formed, steps and process discussed below may be omitted. If more dielectric layers and metallization patterns are to be formed, steps and processes discussed below may be repeated.

In some embodiments, the dielectric layer 124 is deposited on the encapsulant 156, through vias 154, and integrated component packages 160. In some embodiments, the dielectric layer 124 is formed of a photo-sensitive material such as PBO, polyimide, BCB, or the like, which may be patterned using a lithography mask. The dielectric layer 124 may be formed by spin coating, lamination, CVD, the like, or a combination thereof. The dielectric layer 124 is then patterned. The patterning forms openings exposing portions of the through vias 154 and the die connectors 162 (see FIG. 9). The patterning may be by an acceptable process, such as by exposing and developing the dielectric layer 124 to light when the dielectric layer 124 is a photo-sensitive material or by etching using, for example, an anisotropic etch.

The metallization pattern 126 is then formed. The metallization pattern 126 includes conductive elements extending along the major surface of the dielectric layer 124 and extending through the dielectric layer 124 to physically and electrically couple to the through vias 154 and the integrated component packages 160. As an example to form the metallization pattern 126, a seed layer is formed over the dielectric layer 124 and in the openings extending through the dielectric layer 124. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization pattern 126. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the metallization pattern 126. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

In some embodiments, a dielectric layer 128 is deposited on the metallization pattern 126 and the dielectric layer 124. The dielectric layer 128 may be formed in a manner similar to the dielectric layer 124, and may be formed of a similar material as the dielectric layer 124.

The metallization pattern 130 is then formed. The metallization pattern 130 includes portions on and extending along the major surface of the dielectric layer 128. The metallization pattern 130 further includes portions extending through the dielectric layer 128 to physically and electrically couple the metallization pattern 126. The metallization pattern 130 may be formed in a similar manner and of a similar material as the metallization pattern 126. In some embodiments, the metallization pattern 130 has a different size than the metallization pattern 126. For example, the conductive lines and/or vias of the metallization pattern 130 may be wider or thicker than the conductive lines and/or vias of the metallization pattern 126. Further, the metallization pattern 130 may be formed to a greater pitch than the metallization pattern 126.

In some embodiments, such as that shown in FIG. 10, additional dielectric layers 132 and 136, as well as metallization pattern 134 are formed by repeating the processes described above. The dielectric layers 132 and 136 may be formed in a manner similar to the dielectric layer 124, and may be formed of a similar material as the dielectric layer 124. The metallization pattern 134 may be formed in a manner similar to metallization patterns 126 and 130, and may be formed of a similar material as metallization patterns 126 and 130.

In the embodiment shown, the metallization pattern 134 is the topmost metallization pattern of the front-side redistribution structure 122. As such, all of the intermediate metallization patterns of the front-side redistribution structure 122 (e.g., the metallization patterns 126 and 130) are disposed between the metallization pattern 134 and the integrated component packages 160. In some embodiments, the metallization pattern 134 has a different size than the metallization patterns 126 and 130. For example, the conductive lines and/or vias of the metallization pattern 134 may be wider or thicker than the conductive lines and/or vias of the metallization patterns 126 and 130. Further, the metallization pattern 134 may be formed to a greater pitch than the metallization pattern 130. Additional dielectric layers and metallization patterns may be included in the front-side redistribution structure 122 by repeating steps described above. If fewer dielectric layers and metallization patterns are desired in the front-side redistribution structure 122, then steps described above may be omitted.

In some embodiments, such as the embodiment shown in FIG. 10, under-bump metallurgies (UBMs) 138 are formed for external connection to the front-side redistribution structure 122. The UBMs 138 have bump portions on and extending along the major surface of the dielectric layer 136, and have via portions extending through the dielectric layer 136 to physically and electrically couple the metallization pattern 134. As a result, the UBMs 138 are electrically coupled to the through vias 154 and the integrated component packages 160. The UBMs 138 may be formed of the same material as the metallization pattern 126. In some embodiments, the UBMs 138 have a different size than the metallization patterns 126, 130, and 134.

In some embodiments, conductive connectors 170 are formed on the UBMs 138. The conductive connectors 170 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 170 may include a conductive material such as solder, copper, aluminum, gold, nickel, silver, palladium, tin, the like, or a combination thereof. In some embodiments, the conductive connectors 170 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 170 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

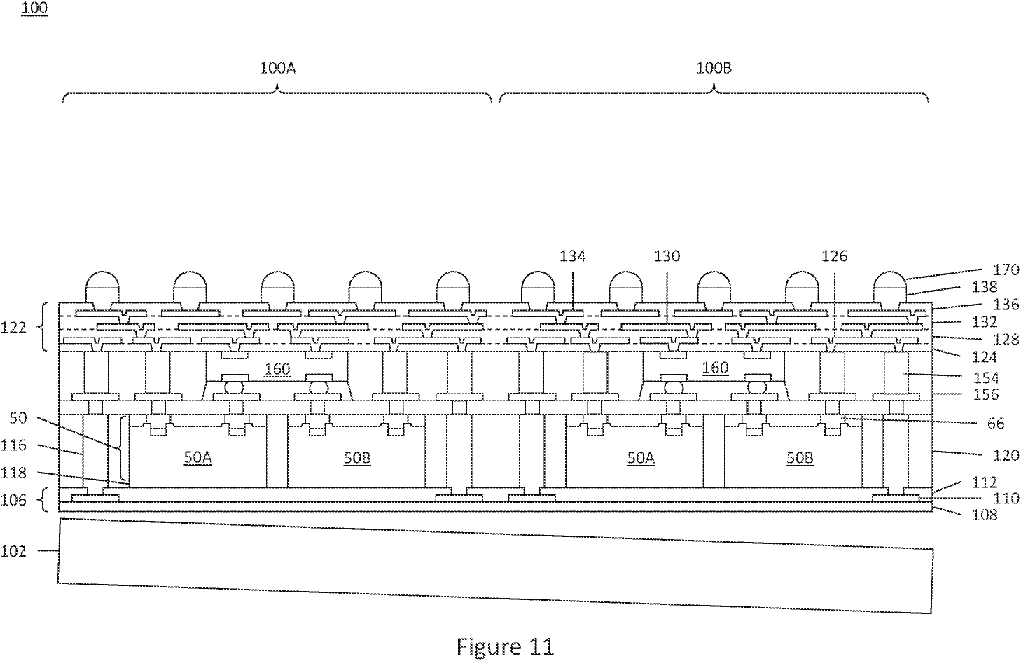

In FIG. 11, a carrier substrate 102 de-bonding is performed to detach (or “de-bond”) the carrier substrate 102 from the back-side redistribution structure 106, e.g., the dielectric layer 108. In accordance with some embodiments, the de-bonding includes projecting a light such as a laser light or an UV light on the release layer 104 so that the release layer 104 decomposes under the heat of the light and the carrier substrate 102 can be removed. The structure is then flipped over and placed on a tape (not shown).

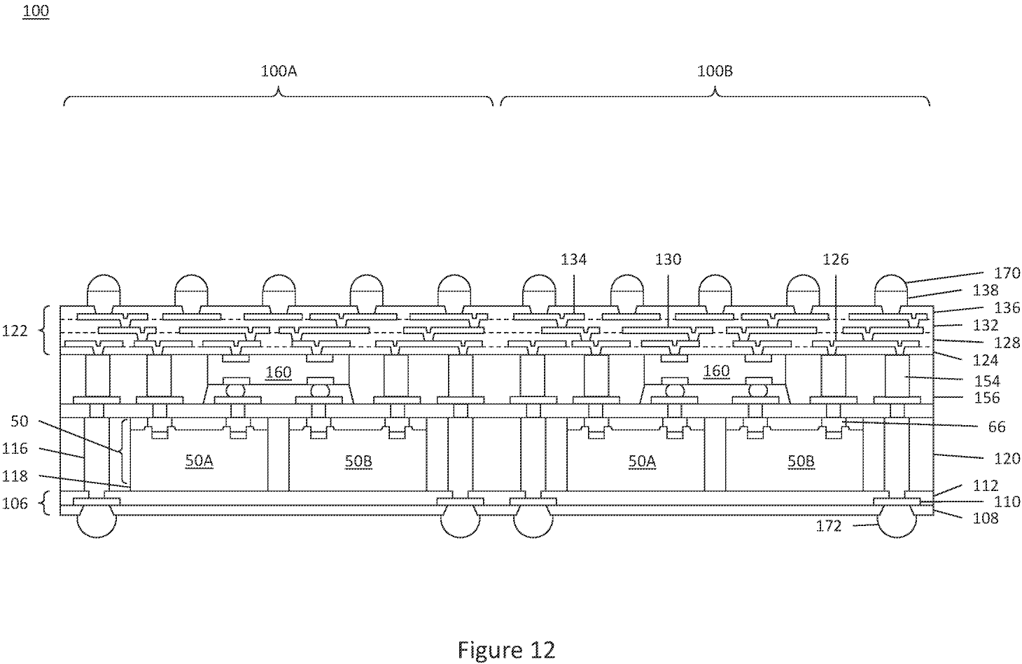

In FIG. 12, conductive connectors 172 are formed extending through the dielectric layer 108 to contact the metallization pattern 110. Openings are formed through the dielectric layer 108 to expose portions of the metallization pattern 110. The openings may be formed, for example, using laser drilling, etching, or the like. The conductive connectors 172 are formed in the openings. In some embodiments, the conductive connectors 172 comprise flux and are formed in a flux dipping process. In some embodiments, the conductive connectors 172 comprise a conductive paste such as solder paste, silver paste, or the like, and are dispensed in a printing process. In some embodiments, the conductive connectors 172 are formed in a manner similar to the conductive connectors 170, and may be formed of a similar material as the conductive connectors 170.

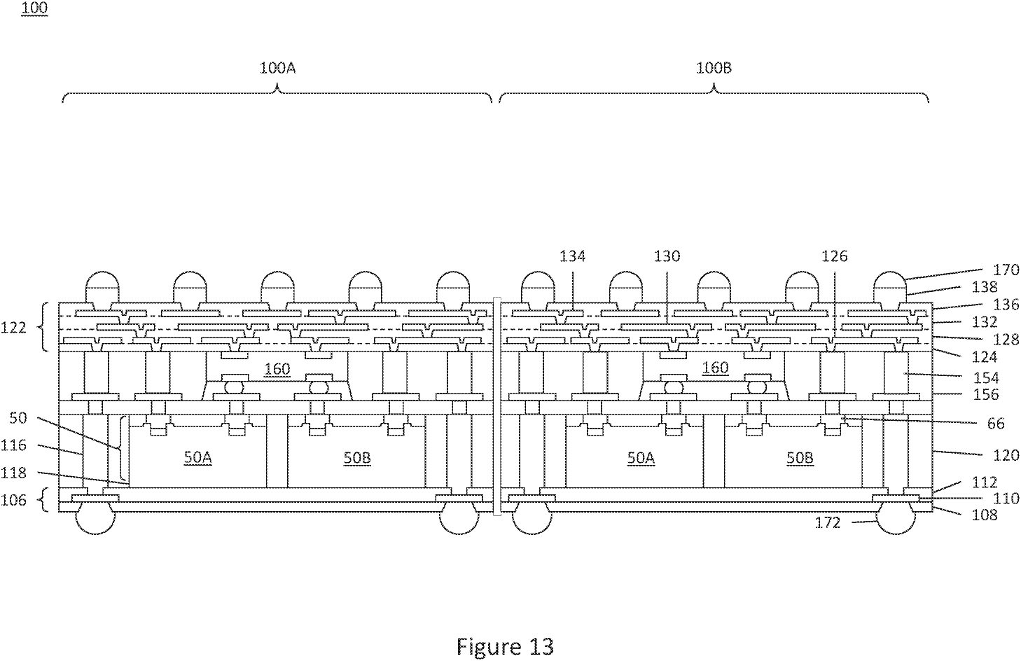

In FIG. 13, a singulation process is performed by sawing along scribe line regions, e.g., between the first package region 100A and the second package region 100B. The sawing singulates the first package region 100A from the second package region 100B. The resulting singulated devices are from one of the first package region 100A and the second package region 100B.

The singulated devices may then be implemented in other device stacks. For example, PoP structures or a Flip Chip Ball Grid Array (FCBGA) package. In such embodiments, the singulated device is mounted to a substrate such as the package substrate. A lid or heat spreader may be attached to the singulated device.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or the 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments may achieve advantages. For example, lower cost, higher efficiency, and increase yield of integrated circuit packages can be realized due to fewer surface and bulk defects of the photoresist and reduced strip time for a wet film process that is approximately 1/10^{th} of the duration of a strip for a conventional dry film lamination process. In some embodiments, a depth of focus of the process window may be improved through the use of the processes described above. In some embodiments, the deviation of the vertical profile of the resulting through vias can be reduced.

In an embodiment, a method of manufacturing a semiconductor device is provided, the method including: receiving a photoresist mixture including: a surfactant 152; and a base solvent; one or more boiling point modifying solvents having a boiling point higher in temperature than the base solvent; and one or more hydrophilicity modifying solvents that are more hydrophilic than the base solvent; depositing the photoresist mixture onto a substrate includes a plurality of under-bump metallurgy layers (UBMLs) using a wet film process; and performing a pre-bake process on the photoresist mixture. In some embodiments, the photoresist mixture further includes a floating cross-linker. In some embodiments, the base solvent is propylene glycol monomethyl ether acetate (PGMEA), the boiling point modifying solvent is methylbutric acid (MBA), and the hydrophilicity modifying solvents is gamma-butyrolactone (GBL). In some embodiments, the wet film process includes a spin coating. In some embodiments, the one or more hydrophilicity modifying solvents are more hydrophilic than each of the one or more boiling point modifying solvents. In some embodiments, the base solvent includes greater than or equal to 90% of the photoresist mixture by atomic weight. In some embodiments, the hydrophilicity modifying solvents includes less than or equal to 1% of the photoresist mixture by atomic weight.

In an embodiment, a method of manufacturing a semiconductor device is provided , the method including: forming a dielectric layer where the dielectric layer is disposed above a substrate; forming through vias in the dielectric layer to provide electrical connection through the dielectric layer to underlying layers; forming a metallization pattern on the through vias and portions of the dielectric layer including under-bump metallurgy layers (UBMLs); forming a photoresist above the dielectric layer and metallization pattern using a wet film process, where forming the photoresist includes depositing a photoresist mixture including a solvent mixture having a base solvent, one or more boiling point modifying solvents having a boiling point higher in temperature than the base solvent, and one or more hydrophilicity modifying solvents that are more hydrophilic than the base solvent, and further where the photoresist mixture forms a floating layer at the top of the photoresist including a surfactant 152 with a higher concentration in the floating layer than in the remainder of the photoresist; performing a pre-bake process to cure the photoresist mixture; patterning the photoresist to expose portions of the metallization pattern; depositing metal in the photoresist; and removing the photoresist. In some embodiments, the photoresist mixture further includes a floating cross-linker that has a higher concentration in the floating layer than in the remainder of the photoresist. In some embodiments, the base solvent is propylene glycol monomethyl ether acetate (PGMEA), the boiling point modifying solvent is methylbutric acid (MBA), and the hydrophilicity modifying solvents is gamma-butyrolactone (GBL). In some embodiments, the wet film process includes a spin coating. In some embodiments, the one or more hydrophilicity modifying solvents are more hydrophilic than each of the one or more boiling point modifying solvents. In some embodiments, the base solvent includes greater than or equal to 90% of the photoresist mixture by atomic weight. In some embodiments, the hydrophilicity modifying solvents includes less than or equal to 1% of the photoresist mixture by atomic weight.

In some embodiments, a photoresist includes: a polymer resin; one or more photoactive compounds (PACs); a surfactant 152; and a solvent mixture including: a base solvent; one or more boiling point modifying solvents having a boiling point higher in temperature than the base solvent; and one or more hydrophilicity modifying solvents that are more hydrophilic than the base solvent. In some embodiments, the photoresist includes a floating cross-linker. In some embodiments, the base solvent is propylene glycol monomethyl ether acetate (PGMEA), the boiling point modifying solvent is methylbutric acid (MBA), and the hydrophilicity modifying solvents is gamma-butyrolactone (GBL). In some embodiments, the one or more hydrophilicity modifying solvents are more hydrophilic than each of the one or more boiling point modifying solvents. In some embodiments, the base solvent includes greater than or equal to 90% of the solvent mixture by atomic weight. In some embodiments, the hydrophilicity modifying solvents includes less than or equal to 1% of the solvent mixture by atomic weight.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, the method comprising:
receiving a photoresist mixture comprising:
a surfactant; and
a base solvent;
one or more boiling point modifying solvents having a boiling point higher in temperature than the base solvent; and
one or more hydrophilicity modifying solvents that are more hydrophilic than the base solvent;
depositing the photoresist mixture onto a substrate comprising a plurality of under-bump metallurgy layers (UBMLs) using a wet film process; and
performing a pre-bake process on the photoresist mixture.

2. The method of claim 1, wherein the photoresist mixture further comprises a floating cross-linker.

3. The method of claim 1, wherein the base solvent is propylene glycol monomethyl ether acetate (PGMEA), the boiling point modifying solvent is methylbutric acid (MBA), and the hydrophilicity modifying solvents is gamma-butyrolactone (GBL).

4. The method of claim 1, wherein the wet film process comprises a spin coating.

5. The method of claim 1, wherein the one or more hydrophilicity modifying solvents are more hydrophilic than each of the one or more boiling point modifying solvents.

6. The method of claim 1, wherein the base solvent comprises greater than or equal to 90% of the photoresist mixture by atomic weight.

7. The method of claim 6, wherein the hydrophilicity modifying solvents comprises less than or equal to 1% of the photoresist mixture by atomic weight.

8. A method of manufacturing a semiconductor device, the method comprising:
forming a dielectric layer wherein the dielectric layer is disposed above a substrate;
forming through vias in the dielectric layer to provide electrical connection through the dielectric layer to underlying layers;
forming a metallization pattern on the through vias and portions of the dielectric layer comprising under-bump metallurgy layers (UBMLs);
forming a photoresist above the dielectric layer and metallization pattern using a wet film process, wherein forming the photoresist comprises depositing a photoresist mixture comprising a solvent mixture having a base solvent, one or more boiling point modifying solvents having a boiling point higher in temperature than the base solvent, and one or more hydrophilicity modifying solvents that are more hydrophilic than the base solvent, and further wherein the photoresist mixture forms a floating layer at the top of the photoresist comprising a surfactant with a higher concentration in the floating layer than in the remainder of the photoresist;
performing a pre-bake process to cure the photoresist mixture;
patterning the photoresist to expose portions of the metallization pattern;
depositing metal in the photoresist; and
removing the photoresist.

9. The method of claim 8, wherein the photoresist mixture further comprises a floating cross-linker that has a higher concentration in the floating layer than in the remainder of the photoresist.

10. The method of claim 8, wherein the base solvent is propylene glycol monomethyl ether acetate (PGMEA), the boiling point modifying solvent is methylbutric acid (MBA), and the hydrophilicity modifying solvents is gamma-butyrolactone (GBL).

11. The method of claim 8, wherein the wet film process comprises a spin coating.

12. The method of claim 8, wherein the one or more hydrophilicity modifying solvents are more hydrophilic than each of the one or more boiling point modifying solvents.

13. The method of claim 8, wherein the base solvent comprises greater than or equal to 90% of the photoresist mixture by atomic weight.

14. The method of claim 13, wherein the hydrophilicity modifying solvents comprises less than or equal to 1% of the photoresist mixture by atomic weight.

15. A photoresist comprising:
a polymer resin;
one or more photoactive compounds (PACs);
a surfactant; and
a solvent mixture comprising:
a base solvent;
one or more boiling point modifying solvents having a boiling point higher in temperature than the base solvent; and
one or more hydrophilicity modifying solvents that are more hydrophilic than the base solvent.

16. The photoresist of claim 15, further comprising a floating cross-linker.

17. The photoresist of claim 15, wherein the base solvent is propylene glycol monomethyl ether acetate (PGMEA), the boiling point modifying solvent is methylbutric acid (MBA), and the hydrophilicity modifying solvents is gamma-butyrolactone (GBL).

18. The photoresist of claim 15, wherein the one or more hydrophilicity modifying solvents are more hydrophilic than each of the one or more boiling point modifying solvents.

19. The photoresist of claim 15, wherein the base solvent comprises greater than or equal to 90% of the solvent mixture by atomic weight.

20. The photoresist of claim 19, wherein the hydrophilicity modifying solvents comprises less than or equal to 1% of the solvent mixture by atomic weight.
